(19) United States
(12) Patent Application Publication
(10) Pub. No.: US 2026/0231426 A1
(43) Pub. Date: Aug. 6, 2026

(54) MEMORY DEVICE INCLUDING PASS TRANSISTORS

(71) Applicant: SK hynix Inc., Icheon-si (KR)

(72) Inventors: Chang Woo KANG, Icheon-si (KR); Jin Ho KIM, Icheon-si (KR)

(21) Appl. No.: 19/242,411

(22) Filed: Jun. 18, 2025

(30) Foreign Application Priority Data
Feb. 4, 2025 (KR) 10-2025-0013748

(51) Int. Cl. H10B 43/40; G11C 5/06; G11C 16/04; H01L 23/00; H10B 43/10; H10B 43/35

(52) U.S. Cl. CPC H10B 43/40; G11C 5/063; G11C 16/0483; H10B 43/10; H10B 43/35; H10W 90/792

(57) ABSTRACT

A memory device comprises: a first semiconductor layer comprising a stacked structure that extends in a first horizontal direction and comprises a plurality of electrode layers and a plurality of interlayer insulating layers alternately stacked in a vertical direction, and a plurality of contact plugs penetrating the stacked structure and respectively connected to the plurality of electrode layers; and a second semiconductor layer stacked with the first semiconductor layer and including a plurality of pass transistors respectively connected to the plurality of contact plugs. The plurality of pass transistors and the plurality of contact plugs are arranged in the plurality of connection regions. The plurality of pass transistors and the plurality of contact plugs may be arranged in a plurality of connection regions aligned along the first horizontal direction. The number of pass transistors and the number of contact plugs in each of the plurality of connection regions is same.

### CROSS-REFERENCE TO RELATED APPLICATION

The present application claims priority under 35 U.S.C. § 119(a) to Korean Patent Application No. 10-2025-0013748 filed on Feb. 4, 2025, which is incorporated herein by reference in its entirety.

### BACKGROUND

### 1. Technical Field

Embodiments of the present disclosure relate to a memory device including pass transistors.

### 2. Related Art

Two-dimensional or planar memory devices have evolved to store more data in the same area by utilizing fine patterning processes. However, as circuit linewidths decrease to meet the demand for higher integration, interference between memory cells intensifies, leading to performance degradation and other limitations. In addition to these structural limitations, the need for expensive equipment to pattern fine linewidths inevitably increases manufacturing costs.

As an alternative to overcoming the limitations of two-dimensional memory devices, three-dimensional (3D) memory devices have been proposed. By stacking memory cells in the vertical direction and increasing the number of tiers, 3D memory devices can achieve higher capacity within the same area while providing benefits such as high performance and excellent power efficiency.

A memory device includes a memory cell array and pass transistors that deliver operating voltages to word lines of the memory cell array. In a three-dimensional memory device, to independently apply electrical signals to word lines positioned at different heights, contact plugs must be connected to each word line, and various technologies are being developed to achieve this.

### SUMMARY

Embodiments of the present disclosure may provide a memory device including pass transistors.

The objects of the embodiments of the present disclosure are not limited to those explicitly mentioned in this specification. Other objects not explicitly stated herein can be readily understood by those skilled in the art from the following description.

The embodiments of the present disclosure may provide a memory device comprising: a first semiconductor layer comprising a stacked structure that extends in a first horizontal direction and comprises a plurality of electrode layers and a plurality of interlayer insulating layers alternately stacked in a vertical direction, and a plurality of contact plugs penetrating the stacked structure and respectively connected to the plurality of electrode layers; and a second semiconductor layer stacked with the first semiconductor layer and including a plurality of pass transistors respectively connected to the plurality of contact plugs; wherein the stacked first and second semiconductor layers includes a plurality of connection regions in the first horizontal direction and the plurality of pass transistors and the plurality of contact plugs are arranged in the plurality of connection regions, and the number of pass transistors and the number of contact plugs in each of the plurality of connection regions are the same.

The embodiments of the present disclosure may provide a memory device comprising: a stacked structure extending in a first horizontal direction and comprising a plurality of electrode layers and a plurality of interlayer insulating layers alternately stacked in a vertical direction; a plurality of contact plugs penetrating the stacked structure in the vertical direction and respectively connected to the plurality of electrode layers; a first insulating layer covering the stacked structure and the plurality of contact plugs; and a plurality of bonding pads disposed on one surface of the first insulating layer and connected to the plurality of contact plugs through a plurality of connection wirings, wherein the plurality of contact plugs and the plurality of bonding pads are distributed in a plurality of connection regions and aligned along the first horizontal direction, and wherein the number of contact plugs and the number of bonding pads in each of the plurality of connection regions is equal.

According to embodiments of the present disclosure, a memory device may be provided that reduces wiring bottlenecks.

According to embodiments of the present disclosure, a memory device may be provided that reduces wiring length variations and minimizes loading differences between wires.

The effects of the embodiments of the present disclosure are not limited to those mentioned above, and other advantages not explicitly stated will be readily understood by those skilled in the art from the description of the claims.

### BRIEF DESCRIPTION OF THE DRAWINGS

The present disclosure will be more fully understood from the detailed description provided below and the accompanying drawings, which are provided solely for illustrative purposes and are not intended to limit the scope of the present disclosure.

FIG. 1 is a block diagram of a memory device according to embodiments of the present disclosure.

FIG. 2 is an equivalent circuit diagram of a memory block illustrated in FIG. 1.

FIG. 3 and FIG. 4 are cross-sectional views of a memory device according to an embodiment of the present disclosure.

FIG. 5 is a plan view of a memory device according to an embodiment of the present disclosure.

FIG. 6 is a plan view illustrating contact plugs and dummy plugs arranged in a single connection region of a memory device according to an embodiment of the present disclosure.

FIG. 7 is a plan view illustrating pass transistors arranged in a single connection region of a memory device according to an embodiment of the present disclosure.

FIG. 8 is a plan view illustrating contact plugs, pass transistors, bonding pads, and first connection wirings arranged in a single connection region of a memory device according to an embodiment of the present disclosure.

FIG. 9 to FIG. 10 are plan views illustrating a process of manufacturing a memory device according to embodiments of the present disclosure.

FIG. 11 is a cross-sectional view taken along line A-A′ of FIG. 9.

FIG. 12 is a cross-sectional view taken along line B-B′ of FIG. 9.

FIG. 13 is a cross-sectional view taken along line C-C′ of FIG. 10.

FIG. 14 is a cross-sectional view taken along line D-D′ of FIG. 10.

### DETAIL DESCRIPTION

Hereinafter, embodiments of the present disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, then such details may be omitted. As used herein, terms such as “includes,” “has,” or “is composed of” in relation to a component permits the inclusion of additional components unless terms like “only” are explicitly used. Additionally, unless the context clearly indicates otherwise, expressions in the singular are intended to include their plural forms.

Such denotations as “first,” “second,” “A,” “B,” “(a),” and “(b)” may be used to describe components of the present disclosure. These denotations are intended merely to distinguish one component from another, and are not intended to limit the nature, order, sequence, or number of the components.

In describing positional relationships between components, when two or more components are described as being “connected,” “coupled,” or “linked,” it should be understood that they may be directly “connected,” “coupled,” or “linked,” or an intervening component may be present. Here, the intervening component may be included in one or more of the two or more components that are “connected,” “coupled,” or “linked” to each other.

When terms such as “after,” “next,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the present disclosure will be described in detail with reference to accompanying drawings.

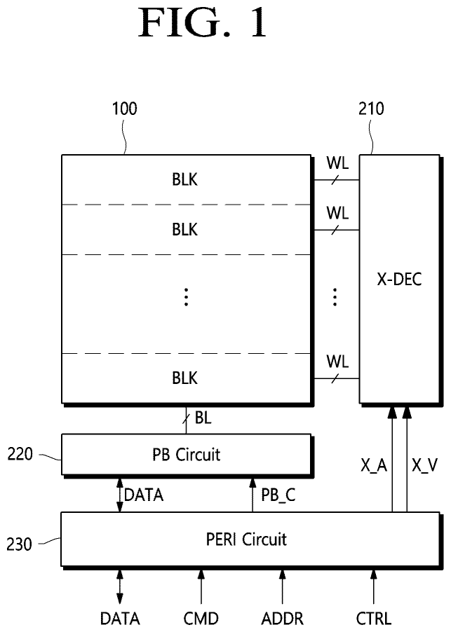

FIG. 1 is a block diagram of a memory device according to embodiments of the present disclosure.

Referring to FIG. 1, a memory device includes a memory cell array 100, a row decoder (X-DEC) 210, a page buffer circuit (PB Circuit) 220, and a peripheral circuit (PERI Circuit) 230.

The memory cell array 100 includes a plurality of memory blocks BLK. Each memory block BLK includes a plurality of memory cells. The memory cells may be, for example, flash memory cells. Hereinafter, memory cells are described as NAND flash memory cells; however, the present inventions are not limited thereto. The memory cells may also be resistive memory cells such as ReRAM, PRAM, or MRAM.

The memory block BLK may be connected to the row decoder 210 through word lines WL. The memory block BLK may be connected to the page buffer circuit 220 through a plurality of bit lines BL.

The row decoder 210 may select one of the plurality of memory blocks BLK included in the memory cell array 100 in response to a row address (X_A) provided from the peripheral circuit 230. The row decoder 210 may transmit an operating voltage (X_V) provided from the peripheral circuit 230, to the word lines WL of the selected memory block.

The page buffer circuit 220 may receive a page buffer control signal (PB_C) from the peripheral circuit 230 and may transmit and receive a data signal (DATA) to and from the peripheral circuit 230. The page buffer circuit 220 may control the bit lines BL arranged in the memory cell array 100 in response to the page buffer control signal (PB_C). For example, the page buffer circuit 220 may detect signals of the bit lines BL of the memory cell array 100 in response to the page buffer control signal (PB_C), to sense data stored in the memory cells of the memory cell array 100 and transmit the data signal (DATA) to the peripheral circuit 230 based on the detected data. The page buffer circuit 220 may apply signals to the bit lines BL based on the data signal (DATA) received from the peripheral circuit 230 in response to the page buffer control signal (PB_C), thereby writing data into the memory cells of the memory cell array 100. The page buffer circuit 220 may write data into or read data from the memory cells connected to the word lines activated by the row decoder 210.

The peripheral circuit 230 may receive a command signal (CMD), an address signal (ADDR), and a control signal (CTRL) from an external device of the memory device, such as a memory controller, and may transmit and receive data (DATA) to and from the memory controller. The peripheral circuit 230 may output signals for writing data into or reading data from the memory cell array 100, such as the row address (X_A) and the page buffer control signal (PB_C), based on the command signal (CMD), the address signal (ADDR), and the control signal (CTRL). The peripheral circuit 230 may generate various voltages required for the operation of the memory device, including the operating voltage (X_V).

Some or all of the row decoder 210, the page buffer circuit 220, and the peripheral circuit 230 may be disposed in a semiconductor layer different from the memory cell array 100. For example, the memory cell array 100 may be disposed in a first semiconductor layer, and the row decoder 210, the page buffer circuit 220, and the peripheral circuit 230 may be disposed in a second semiconductor layer that vertically overlaps with the first semiconductor layer.

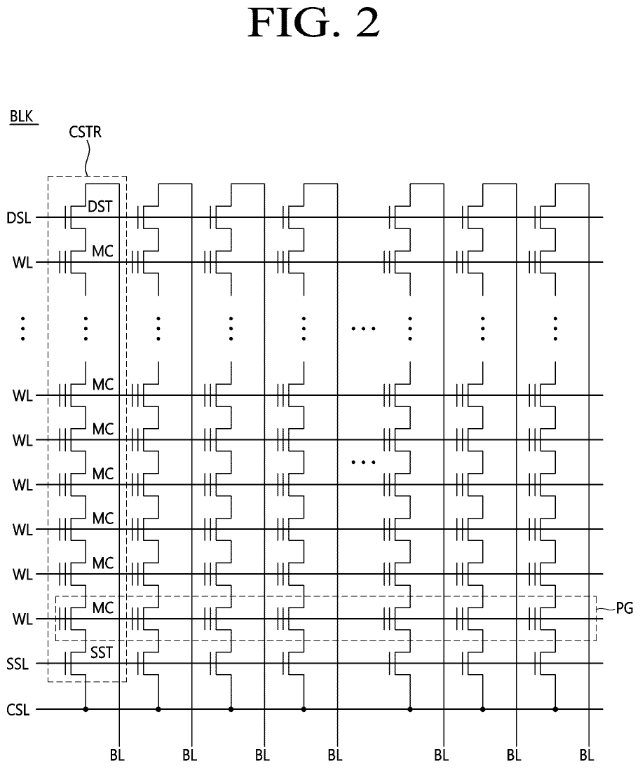

FIG. 2 is an equivalent circuit diagram of a memory block illustrated in FIG. 1.

Referring to FIG. 2, a memory block BLK may include a plurality of cell strings CSTR connected between a plurality of bit lines BL and a common source line CSL.

A cell string CSTR may be connected between a corresponding bit line BL and the common source line CSL. The cell string CSTR may include a source select transistor SST connected to the common source line CSL, a drain select transistor DST connected to the bit line BL, and a plurality of memory cells MC connected between the source select transistor SST and the drain select transistor DST. The gate of the source select transistor SST may be connected to a source select line SSL. The gates of the memory cells MC may be respectively connected to corresponding word lines WL. The gate of the drain select transistor DST may be connected to a drain select line DSL.

The source selects line SSL, the word lines WL, and the drain select line DSL may be arranged in a direction perpendicular to the bit lines BL. The source selects line SSL, the word lines WL, and the drain select line DSL may be stacked in a direction perpendicular to a substrate surface to form a three-dimensional structure.

The memory cells MC included in the memory block BLK may be classified into physical page units or logical page units. For example, memory cells that share a single word line WL and are connected to different cell strings CSTR may constitute a single physical page PG. Such a page may be a basic unit of a read operation.

By way of example, FIG. 2 illustrates that each cell string CSTR is provided with a single drain select transistor DST and a single source select transistor SST. However, each cell string CSTR may include two or more drain select transistors or two or more source select transistors.

Hereinafter, in the accompanying drawings, two directions parallel to the upper surface of a substrate are defined as a first horizontal direction HD1 and a second horizontal direction HD2, and the direction protruding perpendicularly from the upper surface of the substrate is defined as a vertical direction. The first horizontal direction HD1 and the second horizontal direction HD2 may intersect perpendicularly. The first horizontal direction HD1 may be the direction in which the word lines extend, and the second horizontal direction HD2 may be the direction in which the bit lines extend.

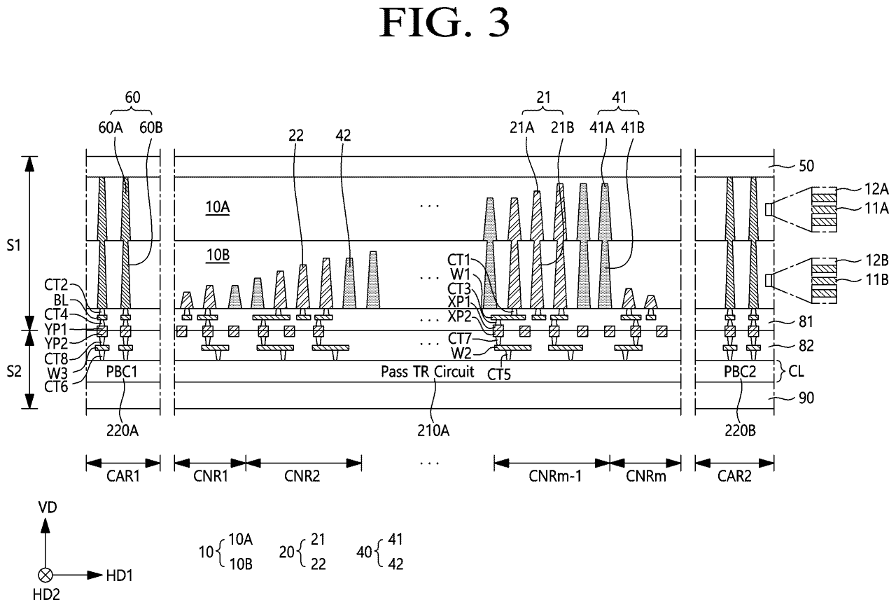

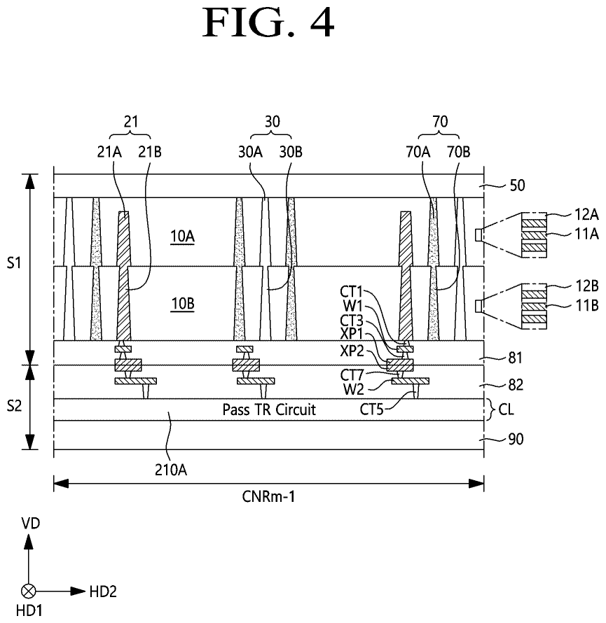

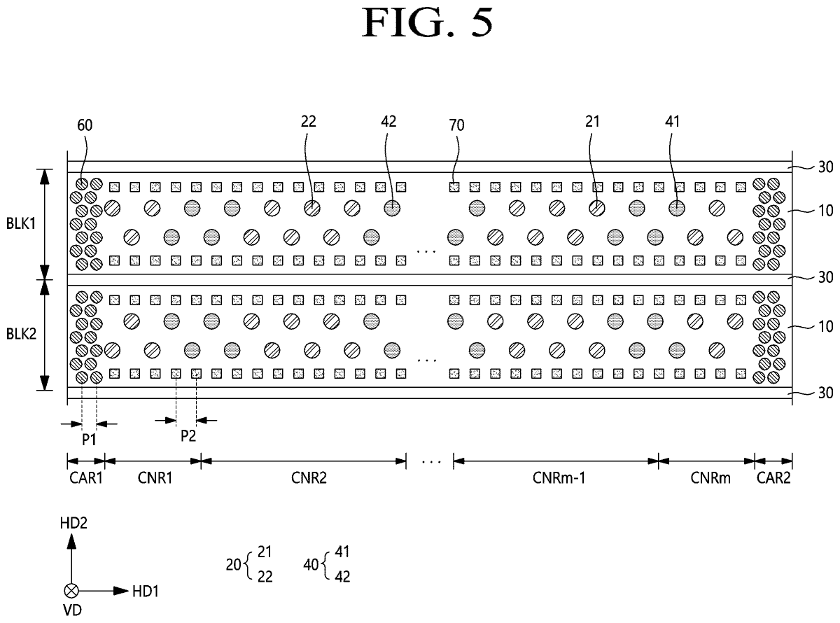

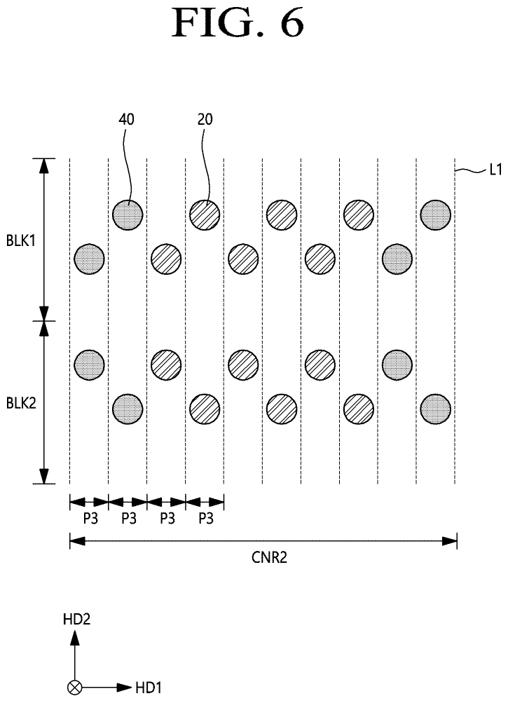

FIG. 3 and FIG. 4 are cross-sectional views of a memory device according to an embodiment of the present disclosure. FIG. 5 is a plan view of a memory device according to an embodiment of the present disclosure. FIG. 6 is a plan view illustrating contact plugs and dummy plugs arranged in a single connection region of a memory device according to an embodiment of the present disclosure.

Referring to FIGS. 3 to 5, a memory device includes a first semiconductor layer S1 and a second semiconductor layer S2.

The memory device includes a first cell region CAR1, a second cell region CAR2, and a plurality of connection regions CNR1 to CNRm. The connection regions CNR1 to CNRm are arranged in a row along a first horizontal direction HD1 between the first cell region CAR1 and the second cell region CAR2. Although in this embodiment, the connection regions CNR1 to CNRm are arranged between the cell regions, the present disclosure is not limited thereto. In other embodiments, the connection regions CNR1 to CNRm may also be arranged at the ends of the cell regions and not between the cell regions.

The first semiconductor layer S1 includes a stacked structure 10 and contact plugs 20. In addition, the first semiconductor layer S1 includes isolation patterns 30, dummy plugs 40, cell plugs 60, a source plate 50, and supports 70.

The stacked structure 10 is disposed over the first cell region CAR1, the connection regions CNR1 to CNRm, and the second cell region CAR2. The stacked structure 10 includes a first-tier stacked structure 10A and a second-tier stacked structure 10B disposed below the first-tier stacked structure 10A. The first-tier stacked structure 10A includes a plurality of first electrode layers 11A and a plurality of first interlayer insulating layers 12A that are alternately stacked, and the second-tier stacked structure 10B includes a plurality of second electrode layers 11B and a plurality of second interlayer insulating layers 12B that are alternately stacked.

The first and second electrode layers 11A and 11B may include a plurality of word lines and selection lines. For example, the selection lines may include at least one first selection line disposed below the word lines and at least one second selection line disposed above the word lines. The first selection line may be a drain select line, and the second selection line may be a source select line.

The stacked structure 10 is disposed between isolation patterns 30 adjacent to each other in a second horizontal direction HD2. The stacked structure 10 may constitute a memory block. Although FIG. 5 illustrates only two stacked structures 10 forming a first memory block BLK1 and a second memory block BLK2, three or more stacked structures 10 may be arranged along the second horizontal direction HD2.

The isolation pattern 30 is disposed between adjacent stacked structures 10 to isolate the stacked structures 10 adjacent to each other in the second horizontal direction HD2. The isolation patterns 30 are disposed over the first cell region CAR1, the connection regions CNR1 to CNRm, and the second cell region CAR2, and extend parallel to each other along the first horizontal direction HD1.

The isolation pattern 30 may include an insulating film. In another example, at least a portion of the isolation pattern 30 may function as a common source line. In such a case, although not illustrated, at least a portion of the isolation pattern 30 may include a conductive film that serves as a common source line. An insulating film may be disposed between the conductive film and the stacked structure 10 to insulate the conductive film from the stacked structure 10.

The isolation pattern 30 includes a first-tier isolation pattern 30A and a second-tier isolation pattern 30B. The first-tier isolation pattern 30A is disposed between first-tier stacked structures 10A adjacent to each other in the second horizontal direction HD2, and the second-tier isolation pattern 30B is disposed between second-tier stacked structures 10B adjacent to each other in the second horizontal direction HD2.

The upper end of the second-tier isolation pattern 30B is connected to the lower end of the first-tier isolation pattern 30A and has a smaller cross-sectional dimension than the lower end of the first-tier isolation pattern 30A at the connection. The dimension of the isolation pattern 30 may have a discontinuous size at the boundary between the first-tier stacked structure 10A and the second-tier stacked structure 10B.

In the connection regions CNR1 to CNRm, contact plugs 20 penetrate the stacked structure 10 in a vertical direction VD and are connected to corresponding electrode layers. The contact plugs 20 include a first contact plug 21 connected to a first electrode layer 11A of a first-tier stacked structure 10A, and a second contact plug 22 connected to a second electrode layer 11B of a second-tier stacked structure 10B. The first contact plug 21 extends in the vertical direction VD through the second-tier stacked structure 10B to the first-tier stacked structure 10A and penetrates a portion of the thickness of the first-tier stacked structure 10A in the vertical direction VD. The second contact plug 22 penetrates a portion of the thickness of the second-tier stacked structure 10B in the vertical direction VD.

The first contact plug 21 includes a first-tier contact plug 21A and a second-tier contact plug 21B. The first-tier contact plug 21A penetrates a portion of the first-tier stacked structure 10A in the vertical direction VD. The second-tier contact plug 21B penetrates the second-tier stacked structure 10B in the vertical direction VD and is connected to the first-tier contact plug 21A. The upper end of the second-tier contact plug 21B is connected to the lower end of the first-tier contact plug 21A and has a smaller cross-sectional dimension than the lower end of the first-tier contact plug 21A at the connection. The dimension of the first contact plug 21 is discontinuous at the boundary between the first-tier stacked structure 10A and the second-tier stacked structure 10B.

In the connection regions CNR1 to CNRm, dummy plugs 40 may penetrate the stacked structure 10 in the vertical direction VD. The depth of the dummy plug 40 may be the same as the depth of an adjacent contact plug 20, but the present disclosure is not limited thereto. The depth of the dummy plug 40 may be arbitrarily selected. By way of example, the dummy plugs 40 include a first dummy plug 41 and a second dummy plug 42. The first dummy plug 41 extends in the vertical direction VD through the second-tier stacked structure 10B to the first-tier stacked structure 10A and penetrates a portion of the thickness of the first-tier stacked structure 10A in the vertical direction VD. The second dummy plug 42 penetrates a portion of the thickness of the second-tier stacked structure 10B in the vertical direction VD.

In an embodiment, the dummy plugs 40 may be electrically floating. In another embodiment, a constant voltage may be applied to the dummy plugs 40. The constant voltage may be a ground voltage (VSS).

A source plate 50 is disposed over the stacked structures 10. The source plate 50 may include polysilicon.

In the first cell region CAR1 and the second cell region CAR2, a plurality of cell plugs 60 may penetrate the stacked structure 10 in the vertical direction VD and extend to the source plate 50.

A cell plug 60 includes a first-tier cell plug 60A and a second-tier cell plug 60B. The first-tier cell plug 60A penetrates the first-tier stacked structure 10A in the vertical direction VD and is connected to the source plate 50. The second-tier cell plug 60B penetrates the second-tier stacked structure 10B in the vertical direction VD and is connected to the first-tier cell plug 60A. The upper end of the second-tier cell plug 60B is connected to the lower end of the first-tier cell plug 60A and has a smaller cross-sectional dimension than the lower end of the first-tier cell plug 60A at the connection. The dimension of the cell plug 60 is discontinuous at the boundary between the first-tier stacked structure 10A and the second-tier stacked structure 10B.

Although not illustrated, the cell plug 60 may include a channel layer and a gate insulating layer. The channel layer may include polysilicon or monocrystalline silicon and may include a p-type impurity such as boron (B) in some regions. The gate insulating layer may surround an outer wall of the channel layer. The gate insulating layer may include a tunnel insulating film, a charge storage film, and a blocking film sequentially stacked from the outer sidewall of the channel layer. In some embodiments, the gate insulating layer may have an ONO (Oxide-Nitride-Oxide) stacked structure in which an oxide film, a nitride film, and an oxide film are sequentially stacked.

A support 70 may penetrate the stacked structure 10 in the vertical direction VD. The support 70 may support the stacked structure 10 to prevent it from collapsing or bending. The support 70 may be made of an insulating material, which may include an oxide.

The support 70 includes a first-tier support 70A and a second-tier support 70B. The first-tier support 70A penetrates the first-tier stacked structure 10A in the vertical direction VD. The second-tier support 70B penetrates the second-tier stacked structure 10B in the vertical direction VD and is connected to the first-tier support 70A. The upper end of the second-tier support 70B is connected to the lower end of the first-tier support 70A and has a smaller cross-sectional dimension than the lower end of the first-tier support 70A at the connection. The dimension of the support 70 is discontinuous at the boundary between the first-tier stacked structure 10A and the second-tier stacked structure 10B.

The first semiconductor layer S1 includes a first insulating layer 81 beneath the stacked structure 10, first connection wirings W1 and bit lines BL disposed in the first insulating layer 81, and first bonding pads XP1 and YP1.

The first insulating layer 81 covers the stacked structure 10, contact plugs 20, isolation patterns 30, dummy plugs 40, cell plugs 60, and supports 70. The first insulating layer 81 may include an oxide film and a nitride film. For example, the first insulating layer 81 may include silicon oxide (SiO2), carbon-doped silicon oxide (C-doped SiO₂), silicon nitride (SiN), silicon carbon nitride (SiCN), a polymer, or the like.

The first connection wirings W1 are disposed in the connection regions CNR1 to CNRm. A first connection wiring W1 is connected to a corresponding contact plug 20 through a first contact CT1. The bit lines BL are disposed in the first and second cell regions CAR1 and CAR2. A bit line BL is connected to a corresponding cell plug 60 through a second contact CT2.

The first connection wirings W1 and the bit lines BL may be disposed in the same wiring layer. That is, the first connection wirings W1 and the bit lines BL may be positioned at the same height level in the vertical direction VD.

The lower surfaces of the first bonding pads XP1 and YP1 may be exposed at the lower surface of the first insulating layer 81. The lower surfaces of the first bonding pads XP1 and YP1 may be disposed in the same plane as the lower surface of the first insulating layer 81. The first bonding pads XP1 and YP1 may include a metal. The metal may include, for example, copper (Cu), aluminum (Al), silver (Ag), cobalt (Co), ruthenium (Ru), or an alloy thereof.

The first bonding pads XP1 and YP1 include first row bonding pads XP1 and first column bonding pads YP1. A first row bonding pad XP1 is connected to a corresponding contact plug 20 through a third contact CT3, a first connection wiring W1, and a first contact CT1. A first column bonding pad YP1 is connected to a corresponding cell plug 60 through a fourth contact CT4, a bit line BL, and a second contact CT2.

The second semiconductor layer S2 includes a substrate 90 and a circuit layer CL.

The circuit layer CL includes a pass transistor circuit 210A and page buffer circuits 220A and 220B.

The pass transistor circuit 210A includes a plurality of pass transistors disposed in the connection regions CNR1 to CNRm. The page buffer circuits 220A and 220B include a first page buffer unit 220A disposed in the first cell region CAR1 and a second page buffer unit 220B disposed in the second cell region CAR2.

The second semiconductor layer S2 includes a second insulating layer 82 covering the circuit layer CL, second bonding pads XP2 and YP2 disposed at the upper surface of the second insulating layer 82, and second connection wirings W2 and third connection wirings W3 disposed in the second insulating layer 82.

The second connection wirings W2 are disposed in the connection regions CNR1 to CNRm and are respectively connected to the pass transistor circuit 210A through a fifth contact CT5. The third connection wirings W3 are disposed in the first and second cell regions CAR1 and CAR2 and are respectively connected to one of the first page buffer unit 220A and the second page buffer unit 220B through a sixth contact CT6.

The second connection wirings W2 and the third connection wirings W3 may be disposed in a single wiring layer. In the present disclosure, the second connection wirings W2 and the third connection wirings W3 are disposed in one wiring layer, but the present disclosure is not limited thereto. In other embodiments, the second connection wirings W2 and the third connection wirings W3 may be disposed in two or more wiring layers.

The upper surfaces of the second bonding pads XP2 and YP2 may be exposed at the upper surface of the second insulating layer 82. The upper surfaces of the second bonding pads XP2 and YP2 may be disposed in the same plane as the upper surface of the second insulating layer 82.

The second insulating layer 82 may include an oxide film and a nitride film. For example, the second insulating layer 82 may include silicon oxide (SiO₂), carbon-doped silicon oxide (C-doped SiO₂), silicon nitride (SiN), silicon carbon nitride (SiCN), a polymer, or the like.

The second bonding pads XP2 and YP2 may include a metal. The metal may include, for example, copper (Cu), aluminum (Al), silver (Ag), cobalt (Co), ruthenium (Ru), or an alloy thereof.

The second bonding pads XP2 and YP2 include a second row bonding pad XP2 and a second column bonding pad YP2. The second row bonding pad XP2 is connected to the pass transistor circuit 210A through the seventh contact CT7, the second connection wiring W2, and the fifth contact CT5. The second column bonding pad YP2 is connected to one of the first page buffer unit 220A and the second page buffer unit 220B through the eighth contact CT8, the third connection wiring W3, and the sixth contact CT6.

The lower surface of the first semiconductor layer S1 is bonded to the upper surface of the second semiconductor layer S2. The first row bonding pad XP1 and the second row bonding pad XP2 are bonded to each other, and the first column bonding pad YP1 and the second column bonding pad YP2 are bonded to each other, forming metal bonding interfaces. The first insulating layer 81 and the second insulating layer 82 are bonded to each other, forming an insulating bonding interface.

Referring to FIG. 5 and FIG. 6, in each of the first and second memory blocks BLK1 and BLK2, cell plugs 60 may be arranged in multiple rows. The cell plugs 60 arranged in odd-numbered rows and the cell plugs 60 arranged in even-numbered rows may be offset from each other in the first horizontal direction HD1.

In each row, the cell plugs 60 may be arranged at a constant pitch along the first horizontal direction HD1. The pitch of the cell plugs 60 represents the distance between the centers of adjacent cell plugs in the first horizontal direction HD1. The cell plugs 60 may be arranged with a first pitch P1 along the first horizontal direction HD1.

In each of the first and second memory blocks BLK1 and BLK2, supports 70 may be arranged in two rows. Although, in FIG. 5, supports 70 are arranged in two rows within a single memory block, the present disclosure is not limited thereto. Supports 70 may be arranged in one or more rows within a single memory block.

In each row, the supports 70 may be arranged at a constant pitch along the first horizontal direction HD1. The pitch of the supports 70 represents the distance between the centers of adjacent supports 70 in the first horizontal direction HD1. The supports 70 may be arranged with a second pitch P2 along the first horizontal direction HD1. The second pitch P2 may be larger than the first pitch P1. For example, the second pitch P2 may be twice the first pitch P1.

In each of the first and second memory blocks BLK1 and BLK2, multiple contact plugs 20 are arranged at a constant pitch. The multiple contact plugs 20 are arranged to be aligned with virtual first lines L1, which are arranged at a third pitch P3 along the first horizontal direction HD1. A single connection region, such as the second connection region CNR2, is divided into multiple first sections by the virtual first lines L1, and the contact plug 20 is positioned in one of the multiple first sections. Thus, the contact plugs 20 may be considered to be arranged at the third pitch P3.

The third pitch P3 may be larger than the first pitch P1 and the second pitch P2. The third pitch P3 may be m times the first pitch P1 (where m is greater than 1) and k times the second pitch P2 (where k is greater than 1). For example, m may be 4 and k may be 2. The size of third pitch P3 may be determined based on the first pitch P1 and the second pitch P2.

In a single connection region, such as the second connection region CNR2, the number of contact plugs 20 arranged in a single memory block may be smaller than the number of multiple first sections divided by the virtual first lines L1. As illustrated in FIG. 6, in the second connection region CNR2, the number of first sections divided by the virtual first lines L1 is 10, whereas the number of contact plugs 20 arranged in a single memory block is 6, which is fewer than the number of first sections.

A dummy plug 40 is arranged in an empty first section where no contact plug 20 is placed. The dummy plug 40 is aligned with the virtual first lines L1. The dummy plug 40 is arranged at the same pitch as the multiple contact plugs 20.

In each of the connection regions CNR1 to CNRm, the dummy plug 40 may be arranged closer to another adjacent connection region than the contact plugs 20. For example, in the second connection region CNR2, the dummy plug 40 may be arranged closer to the first connection region CNR1 than the contact plugs 20.

Although the memory device according to an embodiment includes the dummy plug 40, the present disclosure is not limited thereto. As another example, the memory device may not include dummy plugs.

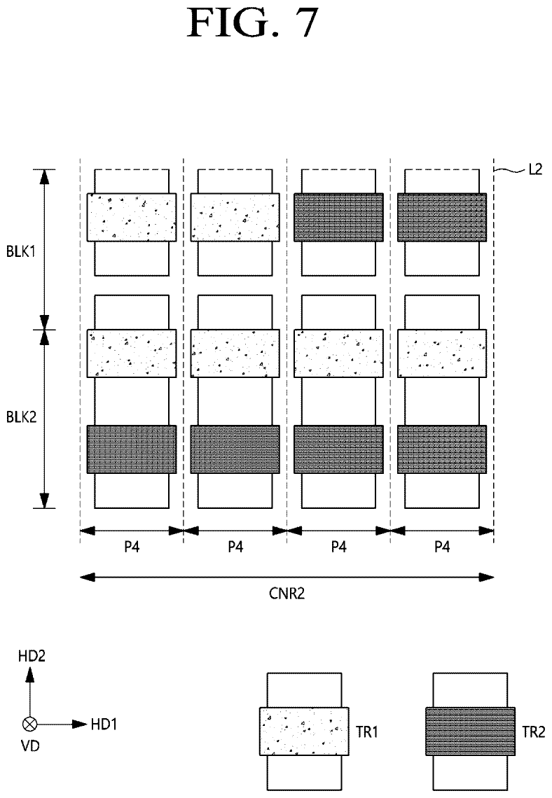

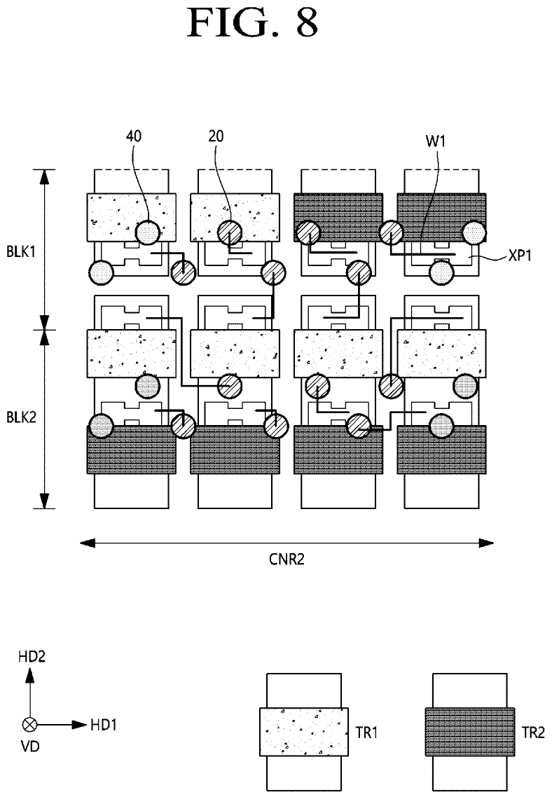

FIG. 7 is a plan view illustrating pass transistors arranged in a single connection region of a memory device according to an embodiment of the present disclosure. FIG. 8 is a plan view illustrating contact plugs, pass transistors, bonding pads, and first connection wirings arranged in a single connection region of a memory device according to an embodiment of the present disclosure.

Referring to FIG. 7, pass transistors TR1 and TR2, which are connected to two memory blocks, for example, the first and second memory blocks BLK1 and BLK2, may be arranged in three rows. The arrangement may be referred to as a 2BLK-3TR structure. Although FIG. 7 illustrates pass transistors arranged in the 2BLK-3TR structure, the present disclosure is not limited thereto. In other embodiments, pass transistors connected to a single memory block may be arranged in one or more rows.

In FIG. 7, TR1 represents a pass transistor connected to the first memory block BLK1, and TR2 represents a pass transistor connected to the second memory block BLK2.

The pass transistors TR1 and TR2 may be arranged to align with virtual second lines L2, which are arranged at a fourth pitch P4 along the first horizontal direction HD1. A single connection region, such as the second connection region CNR2, is divided into multiple second sections by the virtual second lines L2, and one pass transistor is arranged in each of the second sections along the first horizontal direction HD1. Thus, the pass transistors TR1 and TR2 may be considered to be arranged at the fourth pitch P4 in the first horizontal direction HD1. The fourth pitch P4 is larger than the third pitch P3.

Referring to FIG. 8, the number of pass transistors and the number of contact plugs arranged in a single connection region, such as the second connection region CNR2, may be the same. As illustrated in FIG. 8, the number of pass transistors and the number of contact plugs arranged in the second connection region CNR2 each number 8 and are equal.

The number of contact plugs 20 arranged in a single connection region, such as the second connection region CNR2, is equal to the number of first row bonding pads XP1. As illustrated in FIG. 8, the number of contact plugs 20 arranged in the second connection region CNR2 and the number of first row bonding pads XP1 each number 8 and are equal. In an embodiment, the first row bonding pads XP1 may be arranged at the same pitch as the pass transistors TR1 and TR2 in the first horizontal direction HD1.

The contact plugs 20 arranged in a single connection region, such as the second connection region CNR2, are connected to the first row bonding pads (XP1) via first connection wiring W1. The first connection wiring W1 is configured to have a short length in the first horizontal direction HD1. The first connection wiring W1, together with contacts as required, connect the contact plugs 20 and the first row bonding pads XP1 within the second connection region CNR2. The first connection wiring W1 is limited to the second connection region CNR2 when connecting the contact plugs 20 and the first row bonding pads XP1 within the second connection region CNR2. Furthermore, the contact plugs 20 and the first row bonding pads XP1 within a connection region are connected only with first connection wiring W1, which is disposed solely in the same second connection region CNR2.

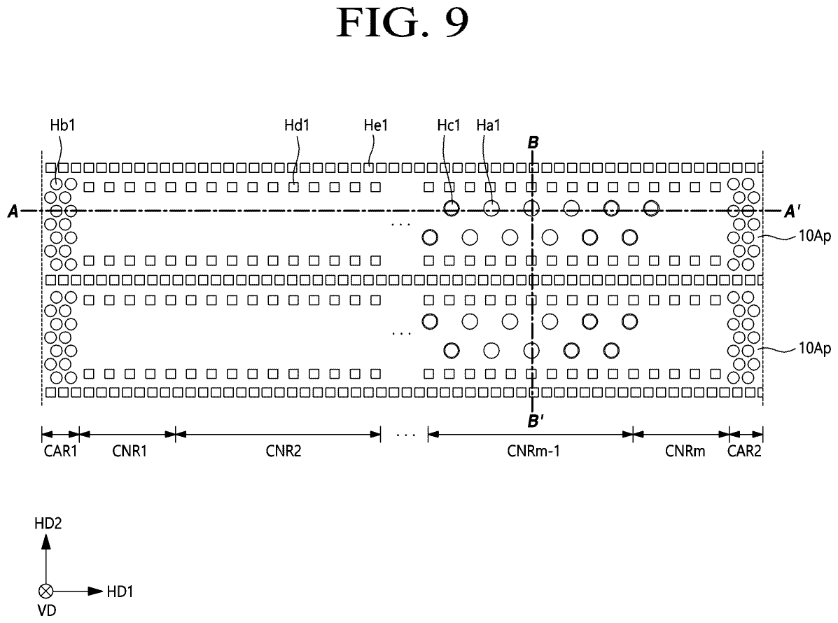

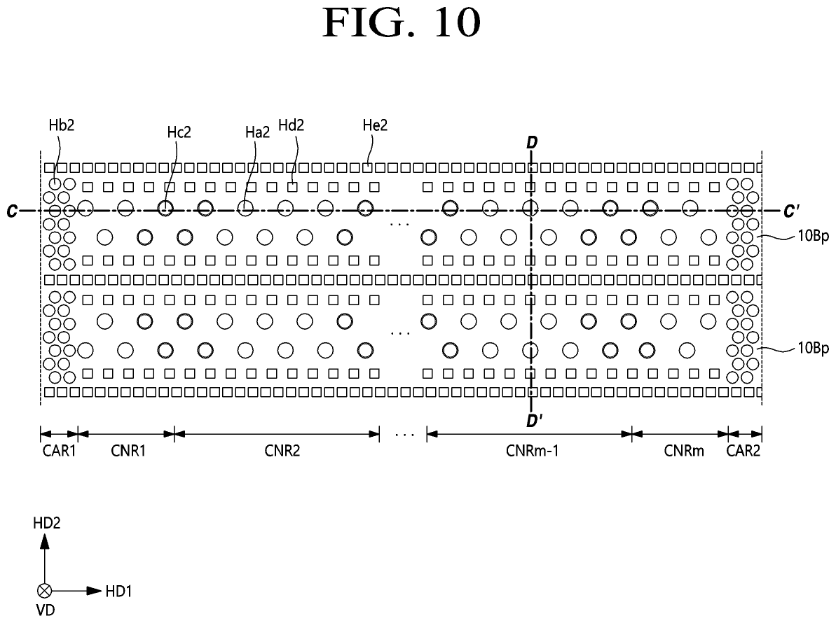

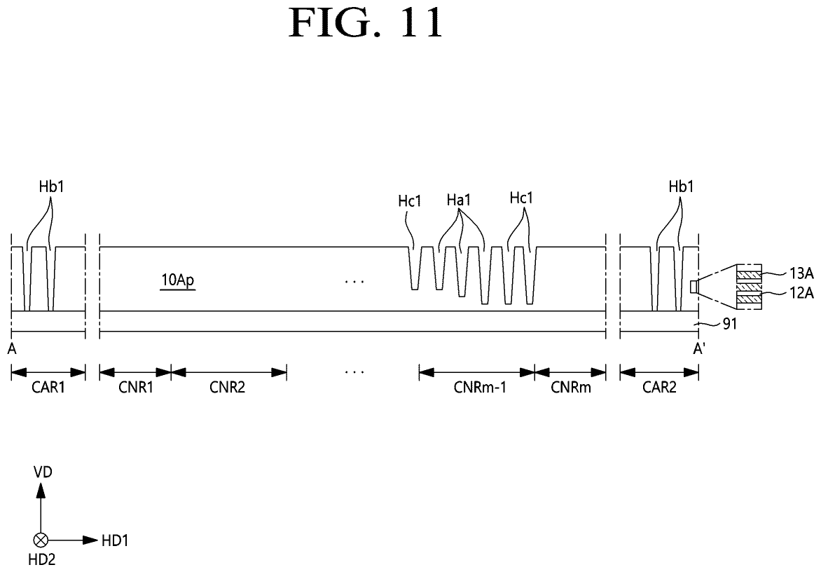

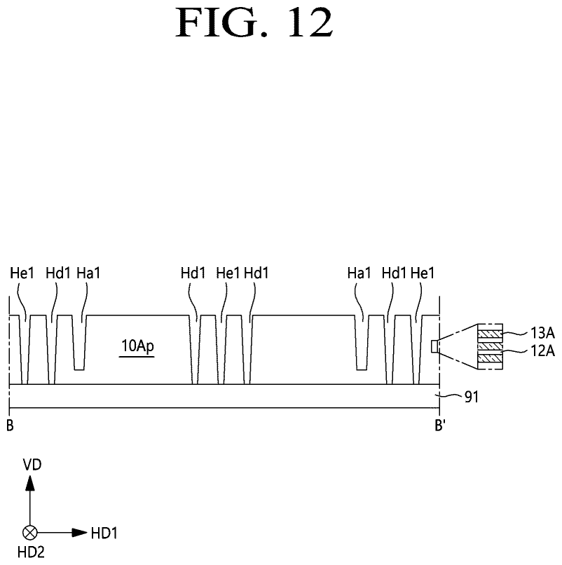

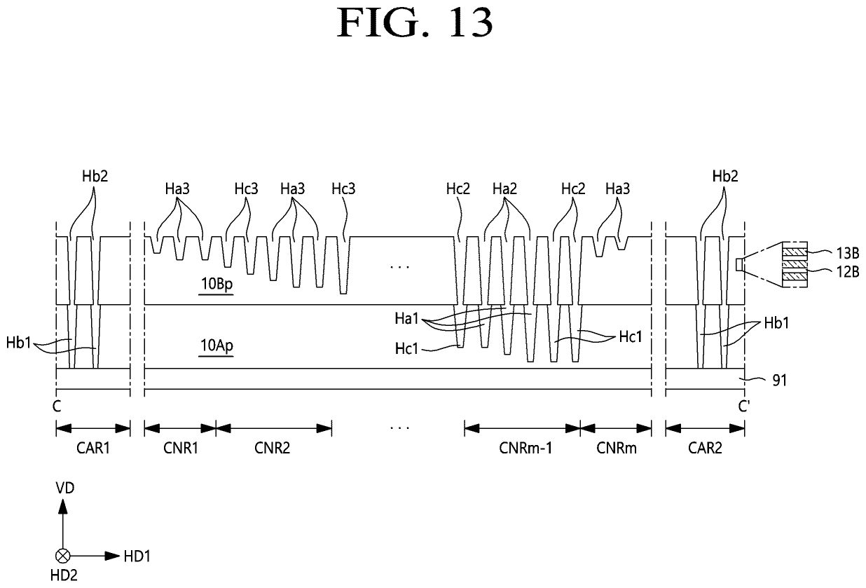

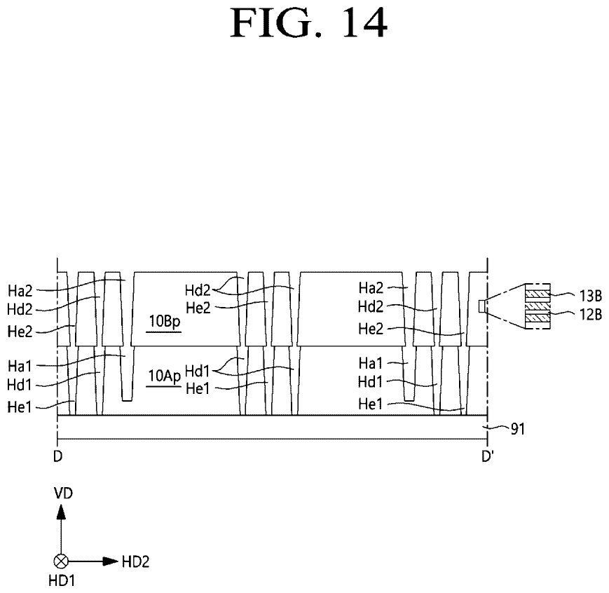

FIG. 9 and FIG. 10 are plan views illustrating a process of manufacturing a memory device according to embodiments of the present disclosure. FIG. 11 is a cross-sectional view taken along the A-A′ line of FIG. 9. FIG. 12 is a cross-sectional view taken along the B-B′ line of FIG. 9. FIG. 13 is a cross-sectional view taken along the C-C′ line of FIG. 10. FIG. 14 is a cross-sectional view taken along the D-D′ line of FIG. 10.

Referring to FIG. 9, FIG. 11, and FIG. 12, a first preliminary stacked structure 10Ap is formed on a preliminary substrate 91, and first plug holes Ha1, first channel holes Hb1, first dummy plug holes Hc1, first support holes Hd1, and first separation holes He1 are formed in the first preliminary stacked structure 10Ap.

The first preliminary stacked structure 10Ap is a pre-structure for forming a first-tier stacked structure 10A in FIG. 3 and includes multiple first interlayer insulating layers 12A and multiple first sacrificial layers 13A, which are alternately stacked. The first sacrificial layers 13A are formed of an insulating material having a different etching selectivity from that of the first interlayer insulating layers 12A. For example, the first interlayer insulating layers 12A includes an oxide, and the first sacrificial layers 13A includes a nitride.

The first plug hole Ha1 may penetrate a portion of the thickness of the first preliminary stacked structure 10Ap to be connected to and to expose one of the first sacrificial layers 13A. The first channel hole Hb1 may penetrate the first preliminary stacked structure 10Ap and extend to expose the preliminary substrate 91. The first dummy plug hole Hc1 may penetrate a portion or the entire thickness of the first preliminary stacked structure 10Ap. The first support holes Hd1 and the first separation holes He1 may penetrate the first preliminary stacked structure 10Ap and extend to expose the preliminary substrate 91.

The first plug hole Ha1, the first channel hole Hb1, the first dummy plug hole Hc1, the first support holes Hd1, and the first separation holes He1 may be formed simultaneously in a single etching process.

Referring to FIG. 10, FIG. 13, and FIG. 14, a second preliminary stacked structure 10Bp is formed on the first preliminary stacked structure 10Ap. Second plug holes Ha2, third plug holes Ha3, second channel holes Hb2, second dummy plug holes Hc2, third dummy plug holes Hc3, second support holes Hd2, and second separation holes He2 are formed in the second preliminary stacked structure 10Bp.

The second preliminary stacked structure 10Bp is a pre-structure for forming a second-tier stacked structure 10B in FIG. 3 and includes multiple second interlayer insulating layers 12B and multiple second sacrificial layers 13B, which are alternately stacked. The second sacrificial layers 13B are formed of an insulating material having a different etching selectivity from that of the second interlayer insulating layers 12B. For example, the second interlayer insulating layers 12B include an oxide, and the second sacrificial layers 13B include a nitride.

The second plug holes Ha2, third plug holes Ha3, second channel holes Hb2, second dummy plug holes Hc2, third dummy plug holes Hc3, second support holes Hd2, and second separation holes He2 may be simultaneously formed in a single etching process.

The second plug hole Ha2 may penetrate the second preliminary stacked structure 10Bp and be connected to the first plug hole Ha1. The third plug hole Ha3 may penetrate a portion of the thickness of the second preliminary stacked structure 10Bp to be connected to and to expose one of the second sacrificial layers 13B. The second channel hole Hb2 may penetrate the second preliminary stacked structure 10Bp and be connected to the first channel hole Hb1. The second dummy plug hole Hc2 may penetrate the second preliminary stacked structure 10Bp and be connected to the first dummy plug hole Hc1. The third dummy plug hole Hc3 may penetrate a portion or the entire thickness of the second preliminary stacked structure 10Bp. The second support hole Hd2 may penetrate the second preliminary stacked structure 10Bp and be connected to the first support hole Hd1. The second separation hole He2 may penetrate the second preliminary stacked structure 10Bp and be connected to the first separation hole He1.

Referring to FIG. 3, although not illustrated, subsequently a first contact plug 21 is formed in the first and second plug holes Ha1 and Ha2; a second contact plug 22 is formed in the third plug hole Ha3; a first dummy plug 41 is formed in the first and second dummy plug holes Hc1 and Hc2; a second dummy plug 42 is formed in the third dummy plug hole Hc3; and a cell plug 60 is formed in the first and second channel holes Hb1 and Hb2. Referring to FIG. 4, a support 70 is formed in the first and second support holes Hd1 and Hd2; slits extending in the first horizontal direction HD1 are formed along the first and second separation holes He1 and He2; and isolation patterns 30 are formed in the slits.

The first plug hole Ha1, first channel hole Hb1, first dummy plug hole Hc1, first support hole Hd1, and first separation hole He1 are simultaneously formed in a single etching process. The second plug hole Ha2, third plug hole Ha3, second channel hole Hb2, second dummy plug hole Hc2, third dummy plug hole Hc3, second support hole Hd2, and second separation hole He2 are simultaneously formed in a single etching process. Accordingly, irregular spacing may occur between the first and second support holes Hd1 and Hd2 and the first and second separation holes He1 and He2 if the first, second, and third plug holes Ha1, Ha2, and Ha3 are formed at arbitrary intervals, especially in the first horizontal direction HD1. This irregularity may lead to process defects during the etching process. To prevent process defects, the pitch of the first, second, and third plug holes Ha1, Ha2, and Ha3 is set as a fixed multiple of the pitch of the first and second separation holes He1 and He2 in the first horizontal direction HD1. Accordingly, the pitch of the contact plugs 20 in FIG. 3 formed in the first, second, and third plug holes Ha1, Ha2, and Ha3 also has a fixed multiple of the pitch of the first and second separation holes He1 and He2 in the first horizontal direction HD1.

Unlike the present disclosure, in comparative art if contact plugs are continuously arranged at a fixed pitch, they will be placed only in some of the connection regions. On the other hand, the first row bonding pads are distributed across the connection regions in accordance with the pitch of the pass transistors. Consequently, while some of the first row bonding pads are positioned close to the target contact plugs, others are positioned farther away. As a result, the length variation of the first connection wirings connecting the first row bonding pads to the contact plugs becomes significant, which may cause signal transmission degradation due to load imbalance among the first connection wirings. Additionally, due to the long lengths of first connection wirings, wiring congestion may occur, making it difficult to arrange the wirings efficiently.

According to embodiments of the present disclosure, the contact plugs and pass transistors are arranged in multiple connection regions along the first horizontal direction, with the same number of pass transistors and contact plugs allocated in each connection region. This arrangement reduces the length of the first connection wirings, alleviates wiring congestion, minimizes the length variation among the first connection wirings, and reduces load imbalance among them.

The above descriptions merely illustrate examples of the technical concept of the present disclosure. A person of ordinary skill in the art to which the present disclosure pertains will be able to make various modifications and changes without departing from the essential characteristics of the present disclosure. Furthermore, the embodiments disclosed herein are provided for illustrative purposes rather than for limiting the scope of the present disclosure. Therefore, the scope of the present disclosure should not be construed as being limited to these embodiments.

What is claimed is:

1. A memory device comprising:
a first semiconductor layer comprising a stacked structure that extends in a first horizontal direction and comprises a plurality of electrode layers and a plurality of interlayer insulating layers alternately stacked in a vertical direction, and a plurality of contact plugs penetrating the stacked structure and respectively connected to the plurality of electrode layers; and
a second semiconductor layer stacked with the first semiconductor layer and including a plurality of pass transistors respectively connected to the plurality of contact plugs,
wherein the stacked first and second semiconductor layers includes a plurality of connection regions in the first horizontal direction, and the plurality of pass transistors and the plurality of contact plugs are arranged in the plurality of connection regions, and
wherein the number of pass transistors and the number of contact plugs in each of the plurality of connection regions is the same.

2. The memory device of claim 1, wherein the plurality of pass transistors and the plurality of contact plugs are respectively aligned in the first horizontal direction and arranged in parallel rows, which are arranged in a second horizontal direction perpendicular to the first horizontal direction.

3. The memory device of claim 2,
wherein virtual first lines extending in the second horizontal direction are arranged at a first pitch in the first horizontal direction and each of the plurality of contact plugs is centered on a different virtual first line.

4. The memory device of claim 3,
wherein virtual second lines extending in the second horizontal direction are arranged at a second pitch along the first horizontal direction, and each of the plurality of pass transistors is centered on a different virtual second line,
wherein the first pitch is different from the second pitch.

5. The memory device of claim 4, wherein the first pitch is smaller than the second pitch.

6. The memory device of claim 3,
wherein the first semiconductor layer further comprises dummy plugs disposed in each of the plurality of connection regions, and
wherein each dummy plug is centered on a virtual first line to be aligned in the first horizontal direction with a row of contact plugs.

7. The memory device of claim 6, wherein from a plan view, in each of the plurality of connection regions, the dummy plugs are disposed closer to an adjacent connection region than the contact plugs.

8. The memory device of claim 2,
wherein the first semiconductor layer further includes a plurality of supports penetrating the stacked structure,
wherein from a plan view each of the plurality of contact plugs is respectively centered on virtual first lines, which extend in the second horizontal direction and are arranged at a first pitch in the first horizontal direction,
wherein the plurality of supports is arranged at a second pitch in the first horizontal direction, and
wherein the first pitch is k times the second pitch, where k is 1 or greater.

9. The memory device of claim 2,
wherein the first semiconductor layer further comprises a plurality of cell plugs penetrating the stacked structure,
wherein from a plan view each of the plurality of contact plugs is respectively centered on virtual first lines, which extend in the second horizontal direction and that are arranged at a first pitch in the first horizontal direction,
wherein the plurality of cell plugs is arranged at a second pitch in the first horizontal direction, and
wherein the first pitch is m times the second pitch, where m is 1 or greater.

10. The memory device of claim 1,
wherein the first semiconductor layer further includes a plurality of first bonding pads and a plurality of connection wirings connecting each of the plurality of contact plugs to a corresponding first bonding pad, and
wherein the second semiconductor layer further includes a plurality of second bonding pads bonded to the plurality of first bonding pads.

11. The memory device of claim 10, wherein the number of first bonding pads and the number of contact plugs arranged in each of the plurality of connection regions is the same.

12. The memory device of claim 10, wherein each of the plurality of connection wirings, which connects the plurality of contact plugs to corresponding first bonding pads within a connection region, is disposed within that connection region.

13. A memory device comprising:
a stacked structure extending in a first horizontal direction and comprising a plurality of electrode layers and a plurality of interlayer insulating layers alternately stacked in a vertical direction;
a plurality of contact plugs penetrating the stacked structure in the vertical direction and respectively connected to the plurality of electrode layers;
a first insulating layer covering the stacked structure and the plurality of contact plugs; and
a plurality of bonding pads disposed on one surface of the first insulating layer and connected to the plurality of contact plugs through a plurality of connection wirings,
wherein the plurality of contact plugs and the plurality of bonding pads are distributed in a plurality of connection regions and aligned along the first horizontal direction, and
wherein the number of contact plugs and the number of bonding pads in each of the plurality of connection regions is equal.

14. The memory device of claim 13, wherein, in each of the plurality of connection regions, the plurality of contact plugs is arranged to be aligned with virtual first lines extending in a second horizontal direction and that are arranged at a first pitch along the first horizontal direction.

15. The memory device of claim 14, wherein the virtual first lines define sections in the plurality of connection regions, and
wherein in each of the plurality of connection regions, the number of contact plugs is smaller than the number of sections defined by the virtual first lines.

16. The memory device of claim 13, further comprising a plurality of dummy plugs arranged in each of the plurality of connection regions,
wherein the plurality of contact plugs and the plurality of dummy plugs are aligned with virtual first lines that are arranged at a first pitch along the first horizontal direction.

17. The memory device of claim 16,
wherein the plurality of connection regions comprises a first connection region and a second connection region that are adjacent to each other,
wherein the plurality of contact plugs comprises first contact plugs arranged in the first connection region, and
wherein the plurality of dummy plugs comprises first dummy plugs arranged in the first connection region and disposed closer to the second connection region than the first contact plugs.

18. The memory device of claim 17,
wherein the plurality of connection wirings comprises first connection wirings connected to the first contact plugs, and
wherein the first connection wirings are arranged within the first connection region.

19. The memory device of claim 13, further comprising a plurality of supports penetrating the stacked structure,
wherein the plurality of contact plugs is arranged to be aligned with virtual first lines extending in a second horizontal direction and that are provided at a first pitch along the first horizontal direction,
wherein the plurality of supports is arranged at a second pitch along the first horizontal direction, and
wherein the first pitch is k times the second pitch, where k is 1 or greater.

20. The memory device of claim 13, further comprising a plurality of cell plugs penetrating the stacked structure,
wherein the plurality of contact plugs is arranged to be aligned with virtual first lines extending in a second horizontal direction and that are provided at a first pitch along the first horizontal direction,
wherein the plurality of cell plugs is arranged at a second pitch along the first horizontal direction, and
wherein the first pitch is m times the second pitch, where m is 1 or greater.
